(19) United States
(12) Patent Application Publication
(10) Pub. No.: US 2006/0016396 A1
(43) Pub. Date: Jan. 26, 2006

(54) Apparatus for depositing a thin film on a substrate

(76) Inventors: Bong-Jin Kuh, Gyeonggi-do (KR); Horii Hideki, Seoul (KR); Soon-Oh Park, Gyeonggi-do (KR); Jang-Eun Lee, Gyeonggi-do (KR); Yong-Ho Ha, Gyeonggi-do (KR)

Correspondence Address: MYERS BIGEL SIBLEY & SAJOVEC, PO BOX 37428, RALEIGH, NC, 27627, US

(21) Appl. No.: 11/179,136

(22) Filed: Jul. 12, 2005

(30) Foreign Application Priority Data
Jul. 23, 2004 (KR) 10-2004-0057760

(51) Int. Cl. C23C 16/00

(52) U.S. Cl. 118/725

(57) ABSTRACT

An apparatus for depositing a thin film on a substrate includes a housing, a substrate support portion, a securing member, a heater, a target member and a plasma generator. The housing defines a process chamber. The substrate support portion is disposed in the process chamber to support the substrate. The securing member is adapted to non-electrically secure the substrate to the substrate support portion during performance of a process. The heater is provided to maintain the substrate supported by the substrate support portion at a process temperature. The target member faces the substrate support portion and includes materials to be deposited on the substrate. The plasma generator is adapted to excite a process gas supplied into the process chamber into a plasma state.

### CROSS-REFERENCE TO RELATED APPLICATION

The present application claims the benefit of priority of Korean Patent Application 2004-57760, filed Jul. 23, 2004, the disclosure of which is hereby incorporated herein by reference in its entirety.

### FIELD OF THE INVENTION

The present invention relates to apparatus for manufacturing semiconductor devices and, more particularly, to an apparatus for depositing a thin film on a substrate.

### BACKGROUND OF THE INVENTION

A semiconductor memory device may include a volatile memory device that loses data in its memory cells when electric power supplied to the device is interrupted or suspended, and a nonvolatile memory device that retains data in its memory cells even when the electric power supplied to the device is shut down. Recently, a phase change storage device having excellent characteristics has been suggested as an example of a new nonvolatile memory device.

The phase change storage device uses a phase change material as a storage medium for data. The phase change material has two stable states, namely, an amorphous state and a crystalline state. The phase change material has a higher resistivity when in the amorphous state than in the crystalline state. Logical information stored in a unit cell of the phase change storage device can be discriminated by sensing a difference in the amount of a current flowing through the phase change material.

A compound containing germanium Ge, tellurium Te, and antimony Sb (which may be referred to as GST or Ge—Te—Sb) is an example of a widely known phase change material. The GST compound is deposited on a wafer by means of a sputtering device. However, upon depositing the phase change material on the wafer using a conventional sputtering device, the compound may not be deposited on the wafer with sufficiently uniform thickness or concentrations of the germanium Ge, the tellurium Te, and the antimony Sb across the regions of the wafer.

### SUMMARY OF THE INVENTION

The present invention is directed to a deposition apparatus capable of depositing a layer or film of a phase change material such as a compound of germanium, tellurium, and antimony on and across an entire prescribed surface or region of a wafer such that the layer is uniform in thickness and composition.

According to embodiments of the present invention, an apparatus for depositing a thin film on a substrate includes a housing, a substrate support portion, a securing member, a heater, a target member and a plasma generator. The housing defines a process chamber. The substrate support portion is disposed in the process chamber to support the substrate. The securing member is adapted to non-electrically secure the substrate to the substrate support portion during performance of a process. The heater is provided to maintain the substrate supported by the substrate support portion at a process temperature. The target member faces the substrate support portion and includes materials to be deposited on the substrate. The plasma generator is adapted to excite a process gas supplied into the process chamber into a plasma state.

The apparatus may further include a magnet member disposed above the target member and including a plurality of magnets to increase a density of a plasma in the vicinity of the target member. An electrode portion can be provided in the substrate support portion to draw ionized particles separated from the target member to the substrate supported by the substrate support portion.

According to some embodiments, the substrate support portion includes a support plate that includes: an upper plate having the electrode portion disposed therein; and a lower plate disposed below the upper plate and having the heater disposed therein. The upper plate can be made of aluminum nitride. The upper plate may include a first plate having the electrode portion disposed therein and a second plate disposed on the first plate and formed of aluminum nitride. In some embodiments, the support plate includes a sheet portion disposed between the upper plate and the lower plate and being formed of carbon and/or copper. According to some embodiments, a groove is formed in an upper surface of the upper plate, and a gas supply path is provided within the support plate to supply gas to the groove. The electrode portion may include only a single electrode or, alternatively, a plurality of electrodes.

According to some embodiments, the apparatus is adapted to deposit a phase change material layer on the substrate. The phase change material layer may include a compound layer containing germanium, tellurium, and antimony.

According to some embodiments, the securing member is adapted to mechanically secure the substrate to the substrate support portion during performance of the process. In some embodiments, the securing member includes a cover portion, the cover portion being positioned at an upper edge portion of the substrate supported by the substrate support portion during the performance of the process.

According to some embodiments, the substrate support portion includes a support plate and a moving portion adapted to raise and lower the support plate, the process chamber housing includes a processing room housing defining a processing room for performance of a deposition process, a through hole is formed in the processing room housing to receive the support plate therethrough, and the securing member is disposed on a lower surface of the processing room housing to engage a side portion of the substrate mounted on the support plate when the support plate is moved into the processing room. The securing member may include a cover portion adapted to engage an upper edge surface of the substrate mounted on the support plate during performance of the process. In some embodiments, a tip end of the cover portion is tapered in a direction toward a center portion of the substrate. The securing member may be formed in a ring shape.

According to further embodiments of the present invention, an apparatus for depositing a phase change material on a substrate includes a process chamber housing defining a process chamber and a substrate support portion disposed in the process chamber to support the substrate. The substrate support portion is adapted to be raised and lowered in the process chamber and includes lower and upper plates. The upper plate is formed of aluminum nitride. A heater is disposed in the lower plate. An electrode is disposed in the upper plate. The apparatus further includes a securing member adapted to non-electrically secure the substrate to the substrate support portion. A target member faces the substrate support portion and includes materials to be deposited on the substrate. A plasma generator is provided which is adapted to excite a process gas supplied into the process chamber into a plasma state. A magnet member is disposed above a target member and includes a plurality of magnets to increase a density of a plasma in the vicinity of the target member.

According to some embodiments, the process chamber housing includes a processing room housing defining a processing room for performing a deposition process. A through hole is formed in a bottom surface of the processing room housing. The substrate support portion further includes a support plate and a moving portion adapted to raise and lower the support plate in the process chamber. The securing member is located in a lower portion of the processing room and is adapted to surround at least a portion of a circumference of the substrate mounted on the support plate when the support plate is inserted into the through hole. In some embodiments, the securing member includes a cover portion positioned at an upper edge portion of the substrate mounted on the support plate during performance of the process. A tip end of the cover portion may be tapered in a direction toward a center portion of the substrate.

The electrode portion may include only a single electrode or, alternatively, a plurality of electrodes.

Further features, advantages and details of the present invention will be appreciated by those of ordinary skill in the art from a reading of the figures and the detailed description of the preferred embodiments that follow, such description being merely illustrative of the present invention.

### BRIEF DESCRIPTION OF THE DRAWINGS

The accompanying drawings are included to provide a further understanding of the invention, and are incorporated in and constitute a part of this specification. The drawings illustrate exemplary embodiments of the present invention and, together with the description, serve to explain principles of the present invention. In the drawings:

FIG. 1 is a schematic cross-sectional view showing a deposition apparatus according to embodiments of the present invention;

FIG. 2 is a bottom view of a magnet member of the apparatus of FIG. 1;

FIG. 3 is a schematic side view showing problems occurring when a deposition apparatus of the prior art is used;

FIG. 4 is a schematic side view showing a line of magnetic force formed when a magnet member according to the present invention is employed in the deposition apparatus of FIG. 1;

FIG. 5 is a schematic side view showing paths of movement of particles from a target of the deposition apparatus of FIG. 1;

FIG. 6 is a schematic side view showing a construction of a substrate support portion of the deposition apparatus of FIG. 1;

FIG. 7 is a schematic side view showing an alternate construction of a substrate support portion of the deposition apparatus of FIG. 1;

FIG. 8 is a schematic cross-sectional view of a wafer mounted on a substrate support portion of the deposition apparatus of FIG. 1 and secured thereto by a securing member;

FIG. 9 is an enlarged cross-sectional view showing the securing member of FIG. 8 in accordance with embodiments of the present invention;

FIG. 10 is an enlarged cross-sectional view showing the securing member of FIG. 8 in accordance with further embodiments of the present invention;

FIG. 11 is a schematic side view showing an exemplary construction and materials of a support plate in accordance with embodiments of the present invention; and

FIG. 12 is a schematic side view showing a further exemplary construction and materials of a support plate in accordance with further embodiments of the present invention.

### Detailed Description of Embodiments of the Invention

The present invention now will be described more fully hereinafter with reference to the accompanying drawings, in which illustrative embodiments of the invention are shown. In the drawings, the relative sizes of regions or features may be exaggerated for clarity. This invention may, however, be embodied in many different forms and should not be construed as limited to the embodiments set forth herein; rather, these embodiments are provided so that this disclosure will be thorough and complete, and will fully convey the scope of the invention to those skilled in the art.

It will be understood that when an element is referred to as being “coupled” or “connected” to another element, it can be directly coupled or connected to the other element or intervening elements may also be present. In contrast, when an element is referred to as being “directly coupled” or “directly connected” to another element, there are no intervening elements present. Like numbers refer to like elements throughout. As used herein the term “and/or” includes any and all combinations of one or more of the associated listed items.

In addition, spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

Well-known functions or constructions may not be described in detail for brevity and/or clarity.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

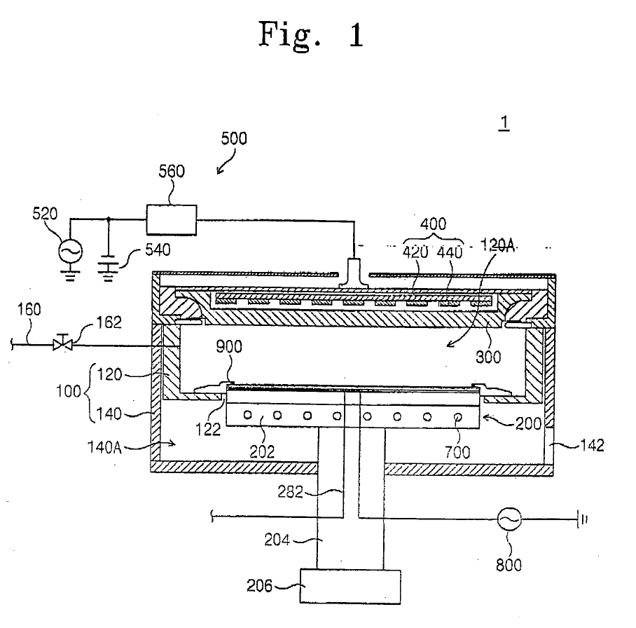

With reference to FIG. 1, a deposition apparatus 1 according to embodiments of the present invention is shown therein. The deposition apparatus 1 can be used to deposit and form a predetermined thin layer or film on a wafer W via a sputtering operation. The apparatus 1 may be used to form a thin film of a phase change material such as a compound layer containing germanium (Ge), tellurium (Te), and antimony (Sb) on the wafer W. The deposition apparatus 1 may also be used to deposit materials other than phase change materials on the wafer W as well.

FIG. 1 is a schematic cross-sectional view of the apparatus 1. The deposition apparatus 1 includes a process chamber housing 100 for receiving the wafer W and providing a process chamber or space for performance of the deposition process. The process chamber housing 100 includes a processing room housing 120 defining a subchamber or processing room 120A for performing the process and a housing 140 surrounding the housing 120 and the processing room 120A. The processing room 120A is located at an upper portion within the housing 140.

A through hole 122 is formed in a bottom wall of the housing 120. A support plate 202 of a substrate support portion or assembly 200 is movable through the through hole 122 so that the wafer W when mounted on top of the support plate 202 can be positioned in the processing room 120A. The housing 140 defines a lower subchamber or chamber 140A under the processing room 120A. An entrance port 142 is formed in a sidewall of the housing 140. The entrance port 142 functions as a passage for moving the wafer W into and out of the process chamber 100.

A gas supply tube 160 is connected to a sidewall of the housing 120 and a process gas is introduced into the processing room 120A through the gas supply tube 160. A valve 162 is provided in the gas supply tube 160. The valve 162 is operable to open/close an internal passage and adjust the amount of gas supplied. One or more gas supply tubes 160 may be provided. A discharge tube (not shown) is connected to a lower wall or a sidewall of the housing 120 and is connected with a pump. The pump is used to maintain a pressure suitable for a process in the processing room 120A. Process by-products occurring in the processing room 120A are discharged or exhausted from the processing room 120A through the discharge tube. According to some embodiments, while the process is being performing, a relatively high pressure of from 13 mTorr to 75 mTorr is maintained in the processing room 120A. According to some embodiments, a pressure of from 40 mTorr to 75 mTorr is maintained in the processing room 120A.

A target 300 is located at an upper portion within the processing room 120A and is made of materials to be deposited on the wafer W. The substrate support portion 200 is located at a lower portion within the process chamber housing 100. The wafer W is mounted on the substrate support portion 200. The target 300 has a size and a shape similar to the size and shape of the wafer W. The target 300 is positioned to face the wafer W mounted on the substrate support portion 200. The substrate support portion 200 is adapted to move vertically up and down. The substrate support portion 200 is also adapted to rotate. Prior to performing the process, an upper surface of the substrate support portion 200 is positioned at a waiting position under the processing room 120A in the lower chamber 140A defined by the housing 140. After the wafer W is mounted on a support plate 202, the substrate support portion 200 ascends until an upper surface of the substrate support portion 200 is moved to a process position in the processing room 120A. The wafer W can be loaded/unloaded to and from the substrate support portion 200 by a transfer robot (not shown) through the entrance port 142, respectively, when the substrate support portion 200 is positioned in the waiting position.

According to some embodiments, the target 300 is composed of a compound containing Ge, Te, and Sb. An energy source 500 is connected to the target 300 and excites the process gas supplied into the processing room 120A into a plasma state. The energy source 500 includes a first power supply section 520 for applying a high frequency alternating current power and a second power supply section 540 for applying a direct current (DC) power. A matching device 560 is provided between the target 300 and the energy source 500. According to some embodiments, the first power supply section 540 supplies a high frequency power of about 60 MHz and about 5 kW, and the second power supply section 540 supplies a DC power of about 6 kW.

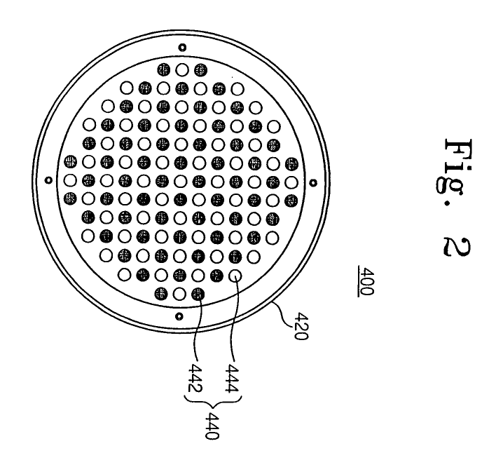

A magnet member 400 is provided above the target 300. The magnet member 400 increases the density of a plasma in the vicinity of the target 300. FIG. 2 is a bottom view of the magnet member 400. With reference to FIG. 2, the magnet member 400 has a plate 420 and a plurality of magnets 440. The magnets 440 protrude downwardly from a lower surface of the plate 420, and adjacent magnets 440 can be arranged to have different polarities. The magnets 440 may be uniformly spaced apart. According to one embodiment of the present invention, the magnets 440 are arranged to form a plurality of rows and columns under the plate 420. The plate 420 may be rotated about a center axis during performance of the process.

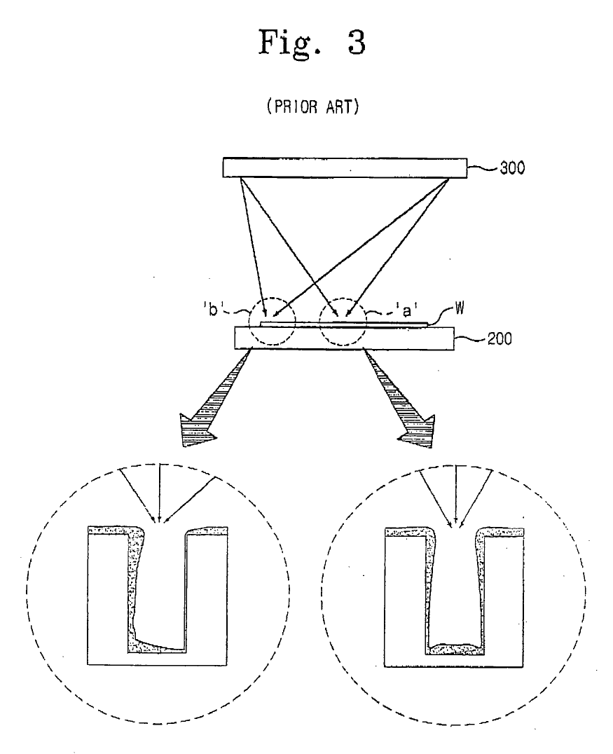

With reference to FIG. 3, in a device of the prior art, the magnet member includes a first magnet and a second magnet. The first magnet has a first polarity and is arranged at the center of the magnet member. The second magnet has a second polarity, and is arranged at an edge of the magnet member in a ring shape. During the performance of a process, a low pressure of from 1 mTorr to 2 mTorr is maintained within the processing room. When the deposition apparatus of the aforementioned construction is used, a line of magnetic force extends a long distance to an adjacent area of the wafer W. Particles separated from the target 300 travel to the wafer W along a slope at a predetermined angle under the influence of the magnetic force line and therefore have a long mean free path to the adjacent surface of the wafer. Accordingly, as shown in FIG. 3, a contact hole may be filled asymmetrically, with a film at a center portion ‘a’ and an edge portion ‘b’ of the wafer W.

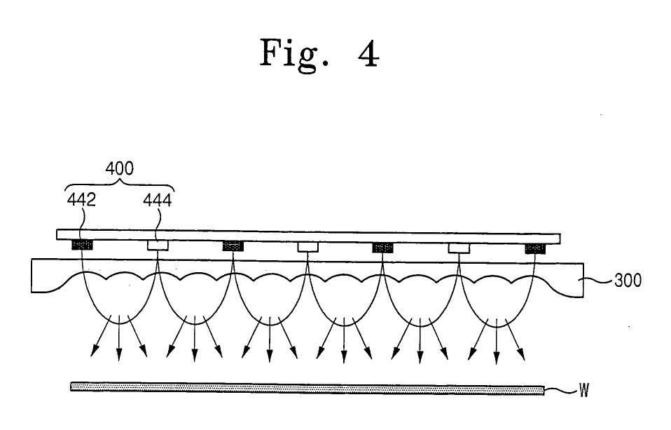

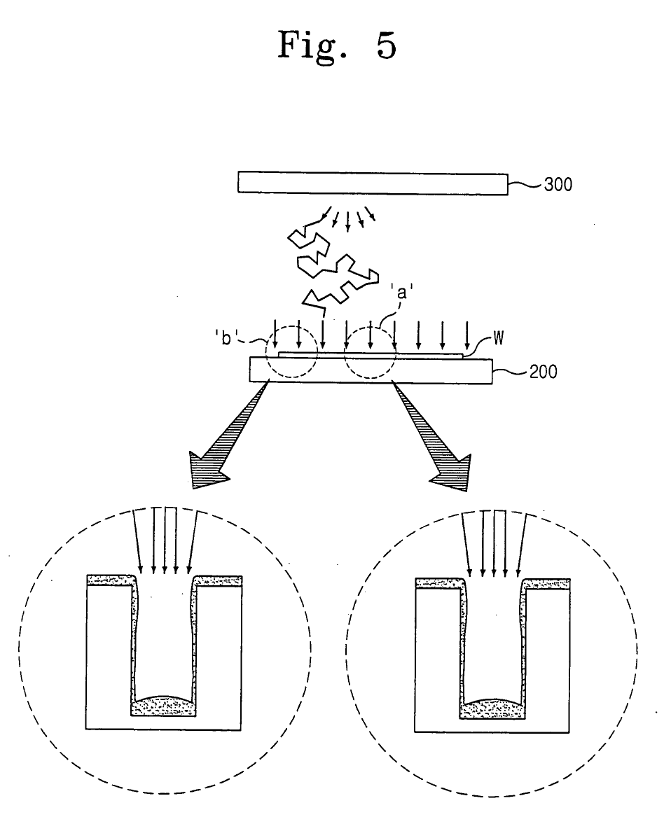

By contrast, using the deposition apparatus 1 or other deposition apparatus in accordance with embodiments of the present invention and as shown in FIG. 4, a strong magnetic field is formed at an area in the vicinity of the target 300, while little or no magnetic field is formed in the vicinity of or proximate the wafer W. Due to the arrangement of the aforementioned magnets 440 and the relatively high pressure in the processing room 120A as discussed above, the ionization ratio of particles separated from the target 300 is high. As shown in FIG. 5, each of the particles has a short mean path and the particles travel generally perpendicularly to the surface of the wafer W. For this reason, the particles are deposited in the contact hole symmetrically about the center portion ‘a’ and the edge portions ‘b’ of the wafer W. Furthermore, the target 300 is uniformly eroded or depleted due to the configuration of the magnets and rotation of the target 300.

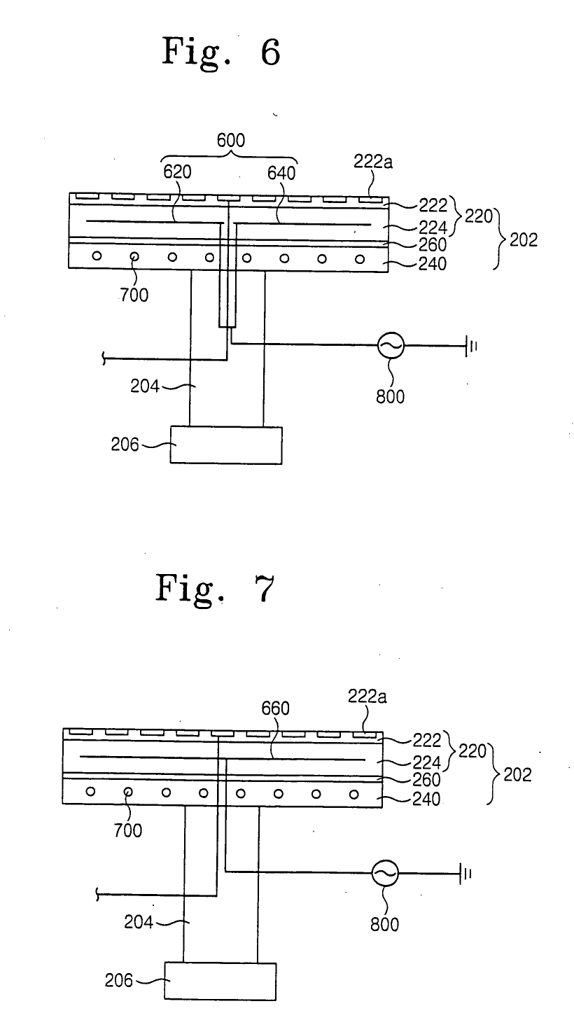

FIG. 6 is a schematic view showing the construction of the substrate support portion 200 shown in FIG. 1. Referring to FIG. 6, a rotating shaft 204 is connected to a rear side of the support plate 202. A driving unit 206 is connected to the rotating shaft 204 and rotates and vertically moves the rotating shaft 204. The rotating shaft 204 may be vertically moved by a hydraulic/pneumatic cylinder or by a mechanism having a pump for precise position control, for example.

A heater 700 is installed within the support plate 202. The heater 700 provides heat to the wafer W mounted on the substrate support portion 200 so that the wafer W maintains a prescribed process temperature during performance of the process. The heater 700 may include a hot plate or a coil-shaped hot wire.

An electrode portion or assembly 600 draws or directs particles separated from the target 300 to the wafer W in a direction perpendicular to the wafer W. According to embodiments of the present invention, for example, a power supply source can supply a high frequency power of about 13.56 MHz and about 1 kW. As shown in FIG. 6, the electrode portion 600 includes a first electrode 620 and a second electrode 640. The shapes and positions of the first and second electrodes 620 and 640 can vary according to process conditions.

Alternatively, the electrode portion 600 may have a single electrode 660 as shown in FIG. 7. As a further alternative, the electrode portion 600 can have three or more electrodes.

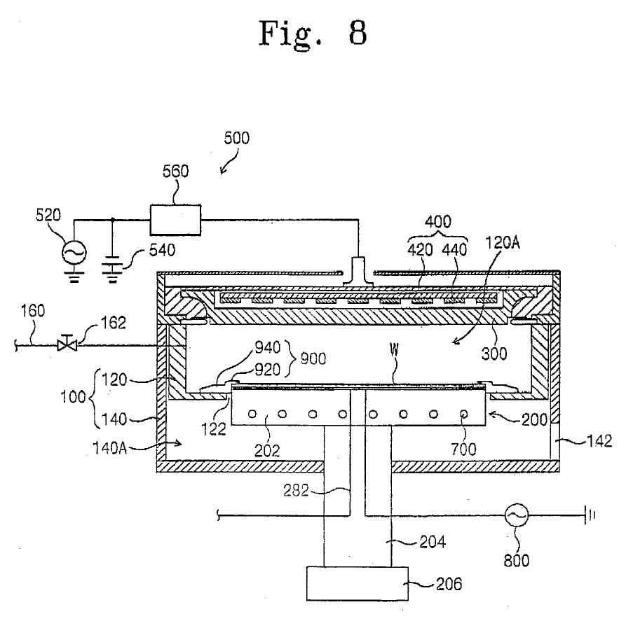

A securing member 900 (FIG. 8) is provided to secure the wafer W to prevent the wafer W from being separated from the substrate support portion 200 and, more particularly, from the support plate 202. Electrically securing the wafer W to the substrate support portion 200 may have advantages and disadvantages as follows. An energy source has a first power supply source and a second power supply source composed of one circuit. The first power supply source applies a radio frequency (RF) power to the electrode portion 600 in order to draw the ionized particles separated from the target to the wafer. The second power supply source applies a DC power to the electrode portion 600 so that the wafer W is stably held to the substrate support portion 200. When the wafer W is electrically held, a uniform temperature is maintained throughout the wafer W. However, a thin film is not deposited in uniform thickness on all regions of the wafer W. Moreover, when the deposited material is a phase change material composed of a compound containing Ge, Te, and Sb, the composition ratio of the deposited material varies as between different regions of the wafer W.

Non-uniformities in the deposition thickness and the composition ratio occur due to a non-uniform field formed on an upper portion of the wafer W. A field is formed on an upper region of the wafer W by the energy source 500 applied to the target 300. The field formed on the aforementioned region by the energy source 500 resonates with the field formed by the energy applied to the electrode portion 600 and thereby causes the non-uniformity. The non-uniform field is caused by the DC voltage applied to the electrode portion 600 to hold the wafer W electrically. According to experimental results, a thick layer having a large amount of Ge forms on a region of the wafer W in the vicinity of the second electrode 640 when a positive voltage is applied thereto. In contrast, a thin film having small amounts of Ge and Sb forms on a region of the wafer W in the vicinity of the first electrode 620 when a negative voltage is applied thereto.

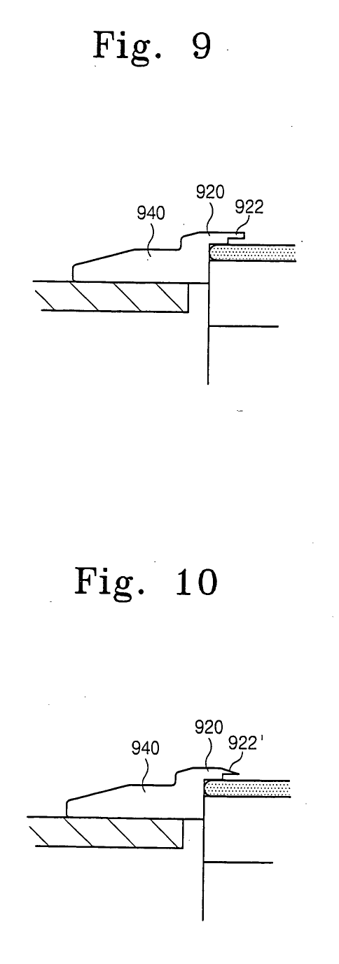

In accordance with the embodiments of the present invention, the securing member 900 fixes the wafer W in a non-electric manner. Preferably, the securing member 900 mechanically holds or secures the wafer W using a mechanical structure. FIG. 8 is a view showing the wafer W secured or coupled to the substrate support portion 200 by the securing member 900. The securing member 900 is fixed and installed on a lower surface of the housing 120 in a lower region of the processing room 120A. The securing member 900 includes a cover member or portion 920 and a sidewall portion 940. When the support plate 202 is set at the process position, the cover portion 920 is positioned at an edge of the wafer W mounted on the support plate 202. Referring to FIG. 9, the sidewall portion 940 extends downwards from a tip end 922 of the cover portion 920. The sidewall portion 940 is arranged to be adjacent to the side portion of the wafer W. The cover portion 920 is arranged to engage and push or positively locate an upper edge surface of the wafer W mounted on the support plate 202 into the process position. The securing member 900 can have a ring shape. Alternatively, a plurality of the securing members 900 can be arranged to wrap the wafer W at predetermined spaced apart locations. As shown in FIG. 9, the end 922 of the cover portion 920 is shaped such that the upper surface thereof extends parallel to the top surface of the wafer W. Alternatively, and as shown in FIG. 10, in order to improve deposition uniformity at the edge of the wafer W, a tip end 922′ of the cover portion 920 can be shaped such that it tapers inwardly (i.e., in the direction of the center of the wafer W) with the top surface of the tip end 922′ sloping downwardly. Although the aforementioned shapes and structures of the securing member 900 may be preferred for mechanically supporting the wafer W, the invention is not limited thereto. It will be apparent to those skilled in the art that the securing member 900 may have various shapes and structures.

When the wafer W is mechanically supported and the upper plate upon which the wafer W is mounted is formed of stainless steel (SUS), variation in the temperature of the wafer W will increase in accordance with the area of wafer W. The deviation in the temperature of the wafer W may have a significant effect on the uniformity of the deposition thickness. In accordance with embodiments of the invention, the substrate support portion 200 is provided to mechanically support the wafer W to provide a uniform temperature distribution throughout the wafer W.

With reference to FIG. 6, the support plate 202 includes an upper plate 220 and a lower plate 240. The upper plate 220 includes a first plate 224 and a second plate 222. The electrode portion 600 is located within the first plate 224. The second plate 222 is disposed on the first plate 224 and is formed in a disc shape having a size similar to that of the wafer W.

A groove 222a (FIG. 6) is formed in the upper surface of the second plate 222. A gas supply path or line 282 (FIG. 1) extends through the support plate 202 and serves as a gas flow path through which gas is supplied to the groove 222a. The gas supply line 282 is connected to an external gas supply tube. An inert gas such as argon is used at the gas. The gas introduced into the groove 222a through the gas supply line 282 causes the heat generated by the heater 700 to be uniformly transferred to the wafer W.

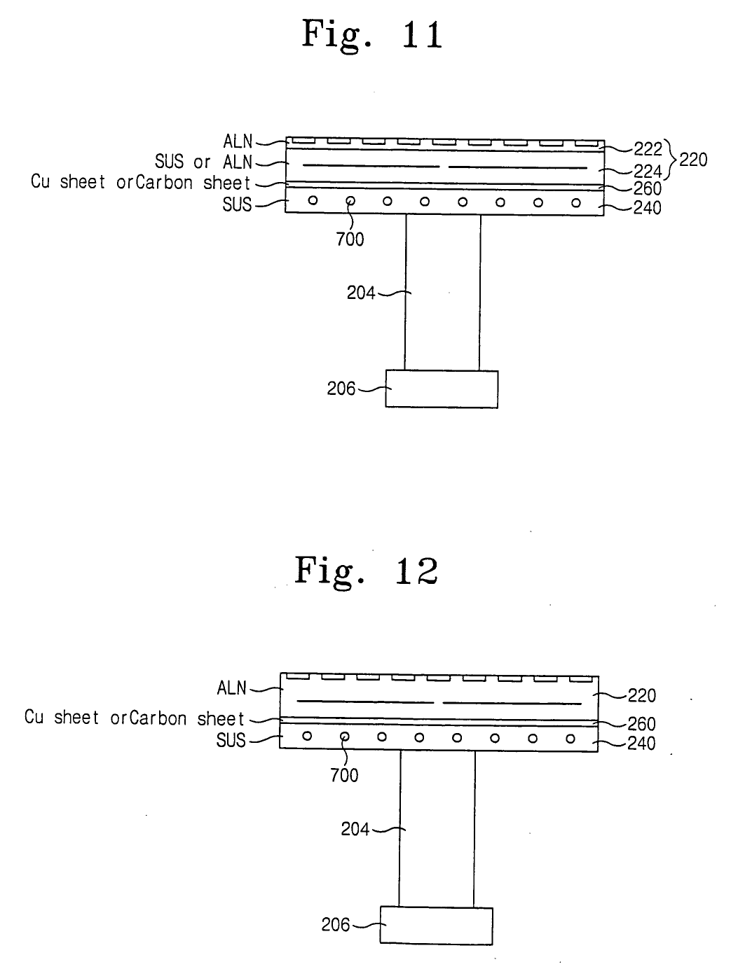

With reference to FIG. 11, according to some embodiments of the present invention, a support plate 220 may be constructed and formed of materials as follows. The second plate 222 may be formed of materials having good or excellent thermal conduction. For example, the second plate 222 may be formed from aluminum nitride (AlN) having excellent thermal conduction. Although the first plate 224 can be made of SUS or AlN, it is preferably made of the same material (e.g., AlN) as the second plate 222 to improve temperature uniformity across the entirety of the wafer W.

Alternatively and as shown in FIG. 12, the first and second plates 224 and 222 can be integrally formed of AlN to form the upper plate 220.

The aforementioned heater 700 is installed within the lower plate 240. The lower plate 240 may be made of SUS. A sheet portion 260 is inserted between the upper plate 220 and the lower plate 240. The sheet portion 260 may be made of carbon or copper to provide effective transfer of heat from the lower plate 240 to the upper plate 220.

According to experimental results, in the case where the upper plate 220 was made of the SUS and the temperature of the wafer W was maintained at 200° C. to 300° C., the temperature deviation across the wafer W was about 3% to 4%.

However, in accordance with an embodiment of the present invention, upon mechanically fixing the wafer W to support portion 200, the temperature deviation across the wafer W was reduced to about 1% to 2% under the same conditions. In this embodiment, because the wafer W was mechanically secured to the substrate support portion 200, the formation of a non-uniform electric field at an upper portion of the wafer W was avoided. The second plate 222 contacting with the wafer W was made of AlN, thereby reducing the temperature deviation between different regions of the wafer W. By adhering a copper or carbon sheet 260 on the lower plate 240 in which the heater 700 was installed, the heat from the heater 700 was substantially uniformly transferred to the wafer W.

In accordance with embodiments of the present invention, a substrate support portion is adapted to mechanically hold a wafer W to a deposition apparatus of the present invention to provide a more uniform electrical field on the wafer W as compared with the conventional method of electrically securing the wafer. Temperature uniformity across the entire width of the wafer W can be improved by forming the part of the substrate support portion contacting the wafer W of AlN having good thermal conduction characteristics. Therefore, when depositing a phase change material layer containing Ge, Te, and Sb on the wafer, a deposition having a uniform thickness and a uniform composition ratio of respective materials can be formed across the entirety of the wafer.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the invention.

What is claimed is:

1. An apparatus for depositing a thin film on a substrate, the apparatus comprising:
a housing defining a process chamber;
a substrate support portion disposed in the process chamber to support the substrate;
a securing member adapted to non-electrically secure the substrate to the substrate support portion during performance of a process;
a heater to maintain the substrate supported by the substrate support portion at a process temperature;
a target member facing the substrate support portion and including materials to be deposited on the substrate; and
a plasma generator adapted to excite a process gas supplied into the process chamber into a plasma state.

2. The apparatus as set forth in claim 1, further comprising a magnet member disposed above the target member and including a plurality of magnets to increase a density of a plasma in the vicinity of the target member.

3. The apparatus as set forth in claim 2, further comprising an electrode portion in the substrate support portion to draw ionized particles separated from the target member to the substrate supported by the substrate support portion.

4. The apparatus as set forth in claim 3, wherein the substrate support portion includes a support plate, and wherein the support plate includes:
an upper plate having the electrode portion disposed therein; and
a lower plate disposed below the upper plate and having the heater disposed therein.

5. The apparatus as set forth in claim 4, wherein the upper plate is made of aluminum nitride.

6. The apparatus as set forth in claim 4, wherein the upper plate includes:
a first plate having the electrode portion disposed therein; and
a second plate disposed on the first plate and formed of aluminum nitride.

7. The apparatus as set forth in claim 4, wherein the support plate includes a sheet portion disposed between the upper plate and the lower plate and being formed of carbon and/or copper.

8. The apparatus as set forth in claim 7, wherein a groove is formed in an upper surface of the upper plate, and a gas supply path is provided within the support plate to supply gas to the groove.

9. The apparatus as set forth in claim 4, wherein the electrode portion includes only a single electrode.

10. The apparatus as set forth in claim 4, wherein the electrode portion includes a plurality of electrodes.

11. The apparatus as set forth in claim 3, wherein the apparatus is adapted to deposit a phase change material layer on the substrate.

12. The apparatus as set forth in claim 11, wherein the phase change material layer includes a compound layer containing germanium, tellurium, and antimony.

13. The apparatus as set forth in claim 1, wherein the securing member is adapted to mechanically secure the substrate to the substrate support portion during performance of the process.

14. The apparatus as set forth in claim 13, wherein the securing member includes a cover portion, the cover portion being positioned at an upper edge portion of the substrate supported by the substrate support portion during the performance of the process.

15. The apparatus as set forth in claim 1, wherein the substrate support portion includes a support plate and a moving portion adapted to raise and lower the support plate, the process chamber housing includes a processing room housing defining a processing room for performance of a deposition process, a through hole is formed in the processing room housing to receive the support plate therethrough, and the securing member is disposed on a lower surface of the processing room housing to engage a side portion of the substrate mounted on the support plate when the support plate is moved into the processing room.

16. The apparatus as set forth in claim 15, wherein the securing member includes a cover portion adapted to engage an upper edge surface of the substrate mounted on the support plate during performance of the process.

17. The apparatus as set forth in claim 16, wherein a tip end of the cover portion is tapered in a direction toward the center portion of the substrate.

18. The apparatus as set forth in claim 16, wherein the securing member is formed in a ring shape.

19. An apparatus for depositing a phase change material on a substrate, the apparatus comprising:
a process chamber housing defining a process chamber;
a substrate support portion disposed in the process chamber to support the substrate, wherein the substrate support portion is adapted to be raised and lowered in the process chamber and includes lower and upper plates, the upper plate being formed of aluminum nitride;
a heater disposed in the lower plate;
an electrode disposed in the upper plate;
a securing member adapted to non-electrically secure the substrate to the substrate support portion;
a target member facing the substrate support portion and including materials to be deposited on the substrate;
a plasma generator adapted to excite a process gas supplied into the process chamber into a plasma state;
a magnet member disposed above a target member and including a plurality of magnets to increase a density of a plasma in the vicinity of the target member.

20. The apparatus as set forth in claim 19, wherein:
the process chamber housing includes a processing room housing defining a processing room for performing a deposition process;
a through hole is formed in a bottom surface of the processing room housing;
the substrate support portion further includes a support plate and a moving portion adapted to raise and lower the support plate in the process chamber; and
the securing member is located in a lower portion of the processing room and is adapted to surround at least a portion of a circumference of the substrate mounted on the support plate when the support plate inserted into the through hole.

21. The apparatus as set forth in claim 20, wherein the securing member includes a cover portion positioned at an upper edge portion of the substrate mounted on the support plate during performance of the process.

22. The apparatus as set forth in claim 21, wherein a tip end of the cover portion is tapered in a direction toward the center position of the substrate.

23. The apparatus as set forth in claim 19, wherein the electrode portion includes only a single electrode.

24. The apparatus as set forth in claim 19, wherein the electrode portion includes a plurality of electrodes.
